(19) United States
(12) Patent Application Publication
(10) Pub. No.: US 2014/0002968 A1
(43) Pub. Date: Jan. 2, 2014

(54) COIL COMPONENT AND DISPLAY DEVICE INCLUDING THE SAME

(71) Applicants: Ki Hung Nam, Suwon (KR); Duck Jin An, Suwon (KR); Soon Young Kwon, Suwon (KR)

(72) Inventors: Ki Hung Nam, Suwon (KR); Duck Jin An, Suwon (KR); Soon Young Kwon, Suwon (KR)

(73) Assignee: SAMSUNG ELECTRO-MECHANICS CO., LTD.

(21) Appl. No.: 13/614,031

(22) Filed: Sep. 13, 2012

(30) Foreign Application Priority Data
Jun. 29, 2012 (KR) 10-2012-0070912

(51) Int. Cl. H01F 27/29; H05K 7/00

(52) U.S. Cl. 361/679.01; 336/192

(57) ABSTRACT

There is provided a coil component able to have a small size and significantly reduced thermal deformation in a manufacturing process. The coil component includes a bobbin including a winding part having a coil wound therein and a terminal insertion part having a terminal insertion groove formed therein; and at least one terminal board including a plurality of external connection terminals and insertedly coupled to the terminal insertion part.

### CROSS-REFERENCE TO RELATED APPLICATIONS

This application claims the priority of Korean Patent Application No. 10-2012-0070912 filed on Jun. 29, 2012, in the Korean Intellectual Property Office, the disclosure of which is incorporated herein by reference.

### BACKGROUND OF THE INVENTION

1. Field of the Invention

The present invention relates to a coil component, and more particularly, to a coil component having a small size and significantly reduced thermal deformation in a manufacturing process.

2. Description of the Related Art

Various types of power supply are required in various electronic devices such as a television (TV), a monitor, a personal computer (PC), an office automation (OA) device, and the like. Therefore, these electronic devices generally include power supplies converting alternate current (AC) power supplied from the outside into power appropriate for respective electronic appliances.

Among power supplies, a power supply using a switching mode (for example, a switched mode power supply (SMPS)) has mainly been used. An SMPS includes a switching transformer as a basic element thereof.

Generally, in a switching transformer, core and bobbin sizes may be significantly reduced as compared to the case of those in a general transformer. In addition, the switching transformer may provide the stable supplying of low voltage and low current direct current (DC) power to the electronic appliance. Therefore, a switching transformer has been widely used in electronic appliances that have tended to be miniaturized.

Meanwhile, according to the related art, a bobbin of a coil component has mainly been manufactured using a relatively cheap polyethylene resin, or the like. However, since polyethylene resin is vulnerable to heat, thermal deformation may occur around an external connection terminal due to heat generated in a process of connecting a coil to the external connection terminal and then soldering the coil to the external connection terminal.

In order to solve this defect, there is provided a method of manufacturing a bobbin using a phenolic resin having excellent temperature resistance characteristics. However, in view of characteristics of the phenolic resin material, it is difficult to thinly form a flange, a partition wall, or the like, on the bobbin, such that it is not easy to apply the phenolic resin to a small coil component.

Therefore, a coil component able to be manufactured to have a small size and significantly reduced thermal deformation in a soldering process has been demanded.

### RELATED ART DOCUMENT

Korean Patent Laid-Open Publication No. 2000-0011091

### SUMMARY OF THE INVENTION

An aspect of the present invention provides a coil component having a small size and significantly reduced thermal deformation in a manufacturing process.

Another aspect of the present invention provides a coil component on which external connection terminals may be disposed in various forms.

Another aspect of the present invention provides an integrally formed assembly coil component in which external connection terminals and a bobbin are manufactured separately and are then coupled to each other.

According to an aspect of the present invention, there is provided a coil component including: a bobbin including a winding part having a coil wound therein and a terminal insertion part having a terminal insertion groove formed therein; and at least one terminal board including a plurality of external connection terminals and insertedly coupled to the terminal insertion part.

The terminal board may be insertedly coupled to the terminal insertion groove in a sliding scheme.

The terminal board may be insertedly coupled to the terminal insertion groove while being slid in a direction perpendicular to a direction in which the external connection terminals protrude.

The terminal board may be insertedly coupled to the terminal insertion groove while being slid in a direction opposite to a direction in which the external connection terminals protrude.

The terminal board may include at least one fitting protrusion formed on one surface thereof and the terminal insertion groove may include at least fitting groove into which the fitting protrusion is fitted.

The fitting protrusion of the terminal board may protrude to be elongated in a direction parallel to a direction in which the external connection terminals are disposed.

The terminal insertion groove may be formed as a space having a rectangular form, and an inlet surface of the terminal insertion groove through which the terminal board is inserted and a surface of the terminal insertion groove at which the external connection terminals may be disposed are opened to the outside.

A surface of the terminal insertion groove opposing the inlet surface may be closed, and the terminal board may be supported by the surface of the terminal insertion groove opposing the inlet surface, such that insertion of the terminal board is limited.

An inlet surface of the terminal insertion groove through which the terminal board is inserted may be opened to the outside, and the external connection terminals of the terminal board may be exposed to the outside through the inlet surface.

The terminal board may at least partially protrude outwardly of the terminal insertion groove.

The terminal board may be formed of a material having thermal deformation lower than that of a material of the bobbin.

The bobbin may be formed of a resin material that is easily thermally deformed, and the terminal board may be formed of a resin material having good deformation resistance even at high temperatures.

The bobbin may be formed of any one of polyphenylenesulfide (PPS), a liquid crystal polyester (LCP), polybutyleneterephthalate (PBT), and polyethyleneterephthalate (PET).

The terminal board may be formed of a phenolic resin.

According to another aspect of the present invention, there is provided a coil component including: a bobbin including a winding part having a coil wound therein; and at least one terminal board coupled to the bobbin in a sliding scheme.

The terminal board may include a plurality of external connection terminals disposed in a row.

The terminal board may be provided in plural so that forms or arrangement intervals of the external connection terminals thereof are different from each other, may be selectively coupled to the bobbin, and may be exchangeable from the bobbin.

The terminal board may include at least one fitting groove formed to be elongated in a direction in which it is slid, and the bobbin may include at least one fitting protrusion fitted into the fitting groove of the terminal board.

The bobbin may include at least one fitting groove formed to be elongated in a direction in which the terminal board is slid, and the terminal board may include at least one fitting protrusion fitted into the fitting groove of the bobbin.

According to another aspect of the present invention, there is provided a display apparatus including: a switched mode power supply having at least one coil component as described above mounted on a substrate thereof; a display panel receiving power supplied from the switched mode power supply; and a cover protecting the display panel and the switched mode power supply.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically showing a coil component according to an embodiment of the present invention;

FIG. 2 is an exploded perspective view of FIG. 1;

FIG. 3 is a cross-sectional view of the coil component in FIG. 1;

FIGS. 4A through 4E are partial cross-sectional views of a terminal insertion groove according to another embodiment of the present invention;

FIGS. 5A through 5D are cross-sectional views of a terminal board according to another embodiment of the present invention;

FIG. 6 is a partially exploded perspective view schematically showing a coil component according to another embodiment of the present invention; and

FIG. 7 is an exploded perspective view schematically showing a display device according to the embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

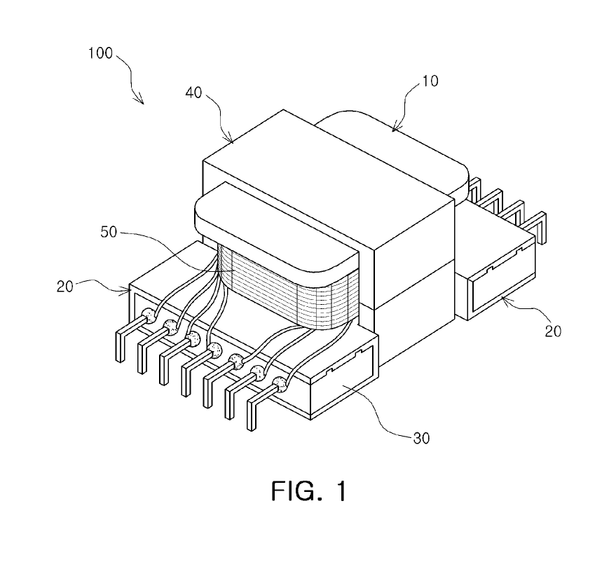

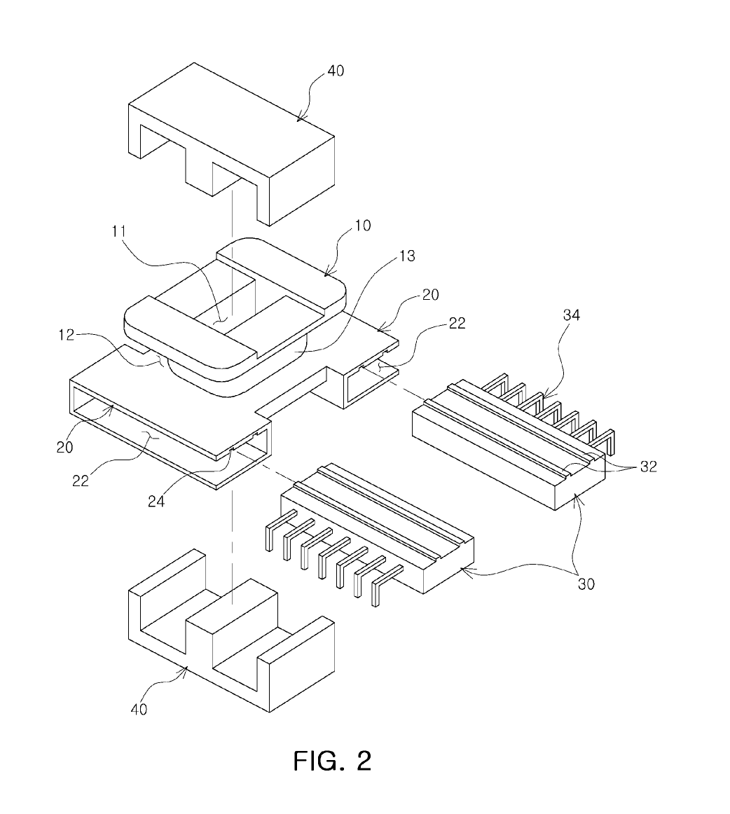

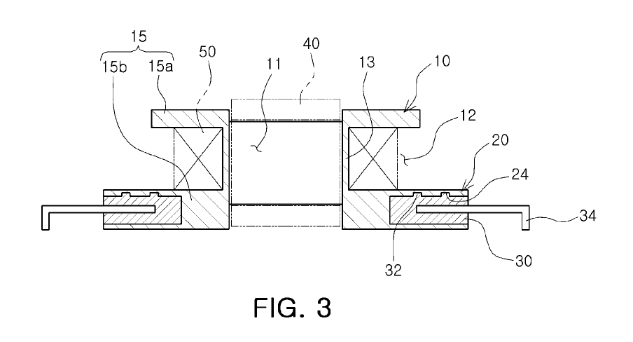

FIG. 1 is a perspective view schematically showing a coil component according to an embodiment of the present invention; FIG. 2 is an exploded perspective view of FIG. 1; and FIG. 3 is a cross-sectional view of the coil component in FIG. 1. In FIGS. 2 and 3, a coil is omitted for convenience of explanation.

Referring to FIGS. 1 through 3, the coil component 100 according to the embodiment of the present invention may be an insulating type switching transformer and may include a bobbin 10, a core 40, a coil 50, and a terminal board.

The bobbin 10 may form an entire body of the coil component. The bobbin 10 may be easily manufactured by injection molding, but is not limited thereto. In addition, the bobbin 10 according to the present embodiment may be formed of an insulating resin and be formed of a material having relatively high heat resistance and relatively high voltage resistance. As a material of the bobbin 10, for example, polyphenylenesulfide (PPS), a liquid crystal polyester (LCP), polybutyleneterephthalate (PBT), polyethyleneterephthalate (PET), phenolic resin, and the like, may be used.

The bobbin 10 may include a winding part 12 having the coil 50 wound therein and a terminal insertion part 20 formed at one end of the winding part 12.

The winding part 12 may include a body part 13 having a pipe form and a flange part 15 extended from both ends of the body part 13 in an outer diameter direction.

An inner portion of the body part 13 may be provided with a through-hole 11 into which a portion of the core 40 is inserted. In addition, the body part 13 may have a coil wound around an outer surface thereof.

The flange part 15 may protrude in a form in which it is extended from both ends, that is, upper and lower ends, of the body part 13 in the outer diameter direction. The flange part 15 according to the present embodiment may be divided into an upper flange part 15a and a lower flange part 15b according to a formation position thereof.

In addition, a space between an outer peripheral surface of the body part 13 and the upper and lower flange parts 15a and 15b may be used as a winding space in which the coil 50 is wound. Therefore, the flange part 15 may serve to protect the coil 50 from the outside and secure an insulation property therebetween, simultaneously with supporting the coil 50 wound in the winding space at both sides thereof.

The terminal insertion part 20 may be formed on the lower flange part 15b. More specifically, the terminal insertion part 20 according to the present embodiment may have a form in which it protrudes from the lower flange part 15b in the outer diameter direction in order to secure an insulation distance.

However, the present invention is not limited thereto. That is, the terminal insertion part 20 may also have a form in which it protrudes downwardly of the lower flange part 15b.

Meanwhile, referring to FIG. 2, since the terminal insertion part 20 according to the present embodiment have a form in which it is partially extended from the lower flange part 15b, it may be difficult to clearly distinguish between the lower flange part 15b and the terminal insertion part 20. Therefore, in the terminal insertion part 20 according to the present embodiment, the lower flange part 15b itself may also be perceived as the terminal insertion part 20.

In addition, the terminal insertion part 20 according to the present embodiment may include a terminal insertion groove 22 which is a space into which a terminal board 30 to be described below is inserted.

The terminal insertion groove 22 may have a form corresponding to that of the terminal board 30 inserted thereinto. In addition, the terminal insertion groove 22 may be formed as a space having an entirely hexahedral form and have a form in which adjacent two surfaces of the hexahedron are opened.

The terminal board 30 according to the present embodiment may be insertedly fitted into the terminal insertion groove 22 in a sliding scheme. Therefore, one surface (hereinafter, referred to as an inlet surface) of the terminal insertion groove through which the terminal board 30 is inserted needs to be completely opened and a surface of the terminal insertion groove on which external connection terminals 34 of the terminal board 30 are disposed also needs to be completely or partially opened.

Meanwhile, in the terminal insertion groove 22 according to the present embodiment, a surface of the terminal insertion groove opposing the inlet surface may be closed. Therefore, the terminal board 30 inserted into the terminal insertion groove 22 is not separated through the surface of the terminal insertion groove opposing the inlet surface, but is supported by the surface of the terminal insertion groove opposing the inlet surface, such that the insertion of the terminal board 30 is limited, whereby the terminal board 30 may be fixed in the terminal insertion groove 22.

In addition, the terminal insertion groove 22 may be provided with at least one fitting groove 24. The fitting groove 24 may be a groove into which a fitting protrusion 32 of a terminal board 30 to be described below is fitted. Therefore, the fitting groove 24 may have a form corresponding to an appearance of the fitting protrusion 32.

The fitting groove 24 may be formed to be elongated in a direction in which the terminal board 30 is slid, similar to the fitting protrusion 32. In the case of the coil component 100 according to the present embodiment, the terminal board 30 may be insertedly coupled to the terminal insertion groove 22 while being slid in a direction perpendicular to a direction in which the external connection terminals 34 protrude. Therefore, the fitting groove 24 may also be formed to be elongated in the direction perpendicular to the direction in which the external connection terminals 34 protrude.

The terminal board 30 according to the present embodiment may be fitted and fixedly inserted into the terminal insertion groove 22. To this end, the terminal insertion groove 22 may have a form in which a width thereof is narrowed as the terminal board 30 progresses toward the surface of the terminal insertion groove opposing the inlet surface. However, the present invention is not limited thereto, but may be variously applied. For example, the fitting groove 24 rather then the terminal insertion groove 22 may be finely narrowed or the terminal board 30 may be finely large.

The bobbin 10 according to the present embodiment as described above may be easily manufactured by an injection molding method, but is not limited thereto. In addition, the bobbin 10 according to the present embodiment may be formed of an insulating resin and be formed of a material having relatively high heat resistance and high voltage resistance. As a material of the bobbin 10, for example, polyphenylenesulfide (PPS), a liquid crystal polyester (LCP), polybutyleneterephthalate (PBT), or the like, may be used. Particularly, polyethyleneterephthalate (PET) may be used.

The terminal board 30 may be inserted into the terminal insertion part 20 of the bobbin 10 to complete the bobbin 10. Therefore, the terminal board 30 may have an entire form corresponding to that of the terminal insertion groove 22. Although the case in which the terminal board 30 has a rectangular parallelepiped form has been described by way of example in the present embodiment, the present invention is not limited thereto.

The terminal board 30 may have a plurality of external connection terminals 34 connected to any one surface thereof. The external connection terminals 34 may protrude outwardly of the terminal board 30 and have various forms according to a form or a structure of the coil component 100 or a structure of a substrate on which the coil component 100 is mounted.

In addition, the terminal board 30 may have at least one fitting protrusion 32 formed on another surface thereof. The fitting protrusion 32 may be a part into which the fitting groove 24 formed in the terminal insertion part 20 is inserted. Therefore, the fitting protrusion 32 may have a form corresponding to that of the fitting groove 24 of the terminal insertion part 20.

Meanwhile, although the case in which the fitting protrusion 32 is formed only on one surface of the terminal board has been described in the present embodiment, the present invention is not limited thereto. That is, a plurality of fitting protrusions 32 may be formed on several surfaces, as needed. In this case, the fitting groove 24 of the terminal insertion groove 22 may also be formed in plural at several positions corresponding to those of the fitting protrusions 32.

In addition, the case in which the fitting protrusion 32 has a form in which it crosses the terminal board 30 has been described by way of example in the present embodiment. However, the present invention is not limited thereto, but may be variously applied as needed. For example, only a single fitting groove 32 may be formed in a protrusion form or a plurality of fitting protrusions may be disposed in a row.

In addition, the terminal board 30 according to the present embodiment may be prepared in various forms and be selectively coupled to the bobbin 10 as needed.

For example, in the terminal boards 30, the number of external connection terminals 34 may be different. In addition, even in the case that the number of external connection terminals 34 in the terminal boards 30 are the same as each other, intervals between the external connection terminals 34 may be different. Further, lengths at which the external connection terminals 34 protrude may be different from each other and directions in which the external connection terminals 34 protrude may be different from each other.

Therefore, in the coil component 100 according to the present embodiment, the terminal boards 30 having various forms as described above may be prepared, and an appropriate terminal board among the terminal boards 30 may be selected according to characteristics of the coil component 100 and be coupled to the bobbin 10.

Meanwhile, the case in which the terminal board 30 is entirely inserted into the terminal insertion groove 22 has been described by way of example in the present embodiment. However, the configuration of the present invention is not necessarily limited thereto, but may be variously applied as needed. For example, a portion of the terminal board 30, that is, a portion at which the external connection terminals 34 are connected may be configured to protrude outwardly of the terminal insertion groove 22 or a side of the terminal board 30 may be configured to protrude outwardly through the inlet surface of the terminal insertion groove 22.

The terminal board 30 may be easily manufactured by injection molding, similar to the bobbin 10, but is not limited thereto. In addition, the terminal board 30 may be formed of an insulating resin and be formed of a material having high heat resistance and high voltage resistance. For example, the terminal board 30 may be formed of a phenolic resin resistant to thermal deformation.

The core 40 may be partially inserted into the through-hole 11 formed in the bobbin 10 and be electromagnetically coupled to the coil 50 to form a magnetic path.

The core 40 according to the present embodiment may be configured in pair. The pair of cores 40 may be partially inserted into the through-hole 11 of the bobbin 10 to thereby be coupled to each other so as to contact each other. As the core 40, an ‘EE’ core, an ‘EI’ core, a ‘UU’ core, a ‘UI’ core, and the like, according to a form thereof may be used.

The core 40 may be formed of Mn—Zn based ferrite having higher permeability, lower loss, higher saturation magnetic flux density, higher stability, and a lower production cost, as compared to other materials. However, in the embodiment of the present invention, a form or a material of the core 40 is not limited.

Meanwhile, in order to secure an insulation property between the coil 50 wound in the bobbin 10 and the core 40, an insulating cover (not shown) may be interposed between the bobbin 10 and the core 40.

The insulating cover may be interposed between the bobbin 10 and the core 40 to correspond to the entire inner surface of the core 40 facing the bobbin 10 or be partially interposed therebetween only at a portion at which the coil 50 and the core 40 face each other.

As the insulating cover, an insulating tape may be used. However, the present invention is not limited thereto.

The coil 50 may be wound in the winding part 12 of the bobbin 10 and include the primary and secondary coils.

Each of the primary coil and the secondary coil may include a plurality of individual coils that are electrically insulated from each other. Here, the number of each of the primary and secondary coils may be appropriately changed as needed.

The primary and secondary coils according to the present embodiment may be wound in a form in which they are stacked in the winding part. In this case, the primary and secondary coils may have the insulating tape interposed therebetween. In addition, after a winding space is partitioned by a partition wall (not shown), the primary and secondary coils may be wound in the partitioned spaces, respectively. In this case, insulation between the primary and secondary coils may be maintained by the partition wall.

As the coil 50 according to the present embodiment, a general insulated coil (for example, a polyurethane wire), or the like, may be used and a twisted pair wire form of coil formed by twisting several strands of wires (for example, a Litz wire, or the like) may be used. In addition, a multi-insulated coil (for example, a triple insulated wire (TIW)) having a relatively high insulation property may be used. That is, a kind of the coil may be selected as needed.

The coil component 100 according to the present embodiment configured as described above may include the terminal board 30, separately from the bobbin 10. In addition, the terminal board 30 may be coupled to the bobbin 10 to provide the external connection terminals 34 at the bobbin 10.

That is, since the terminal board 30 and the bobbin 10 are separately manufactured, the terminal board 30 and the bobbin 10 may be formed of different materials. Therefore, the bobbin 10 is formed of a PET material so as to have a relatively thin thickness, and the terminal board 30 at which the external connection terminals 34 are disposed is formed of a phenolic resin having relatively low thermal deformation, whereby the coil component 100 having a small size and low thermal deformation may be manufactured.

Further, in the coil component 100 according to the present embodiment, various terminal boards 30 may be prepared and be selectively coupled to the bobbin 10 as needed.

For example, a plurality of terminal boards 30 at which the external connection terminals 34 are formed to have different forms or different arrangement intervals are prepared, and any one of the plurality of terminal boards 30 is selected and coupled to the bobbin 10 as needed, whereby the coil component 100 may be completed.

Further, the present invention is not limited to using only any one of the terminal boards 30, but may be variously applied as needed. For example, the terminal board 30 may be replaced by a terminal board 30 having another form.

Therefore, according to the present embodiment, coils having various forms may be selectively wound and used through a single coil component 100, and the connection boards 30 may be appropriately selected and used according to a form or a kind of wound coil, an electrical condition under which the coil component 100 is applied, or the like. Therefore, the coil component 100 according to the present embodiment may be easily used in various devices.

Meanwhile, the present invention is not limited to the above-mentioned configuration, but may be variously applied as needed.

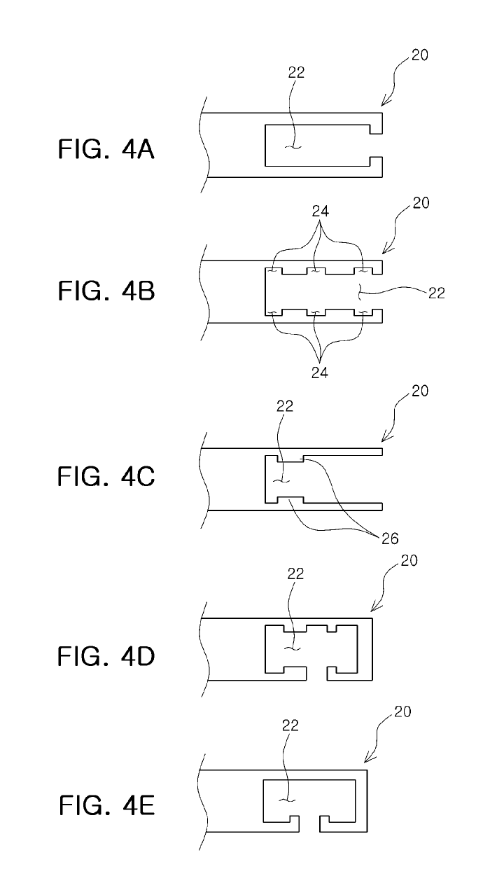

FIGS. 4A through 4E are partial cross-sectional views of a terminal insertion groove 22 according to another embodiment of the present invention.

First referring to FIG. 4A, in the terminal insertion groove 22, the above-mentioned fitting groove 24 (See FIG. 2) is not formed, a surface on which the external connection terminals are disposed is not completely opened, but is partially opened.

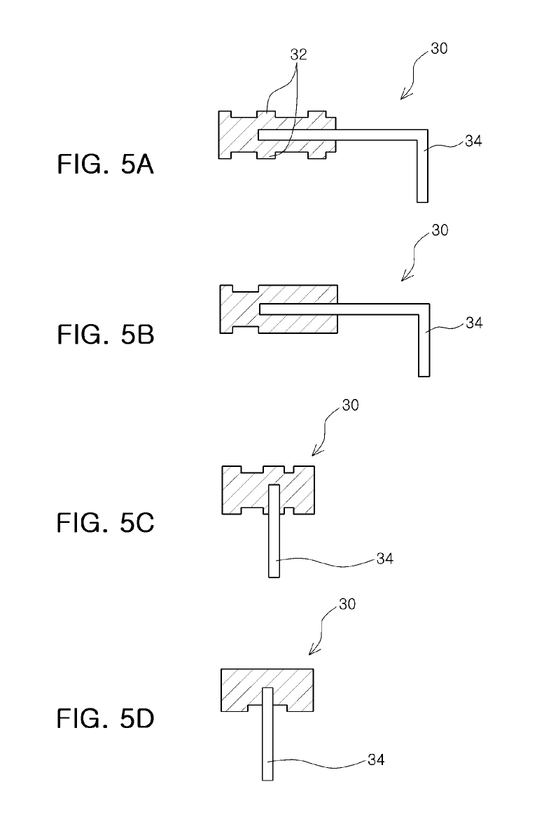

FIG. 4B shows the case in which the fitting grooves 24 are formed in both surfaces facing each other, and FIG. 4C shows the case in which a protrusion 26 is formed on the terminal insertion groove 22. In FIG. 4C, a groove corresponding to this protrusion may be formed in the terminal board inserted into the terminal insertion groove, as shown in FIG. 5B.

FIGS. 4D and 4E show an example of a bobbin in which the external connection terminals are disposed at a lower portion of the bobbin, that is, the case in which an opened surface through which the external connection terminals are exposed is formed on the lower portion of the bobbin.

FIGS. 5A through 5D are cross-sectional views of a terminal board according to another embodiment of the present invention.

FIG. 5A shows an example of the terminal board 30 that may be inserted into the terminal insertion groove 22 shown in FIGS. 4A and 4B.

FIG. 5B shows an example of the terminal board 30 that may be inserted into the terminal insertion groove 22 shown in FIG. 4C, FIG. 5C shows an example of the terminal board 30 that may be inserted into the terminal insertion groove 22 shown in FIG. 4D, and FIG. 5D shows an example of the terminal board 30 that may be inserted into the terminal insertion groove 22 shown in FIG. 4E.

As described above, the coil component 100 according to the present embodiment may be changed in various forms as long as the fitting protrusion 32 formed on any one of the terminal insertion groove 22 and the terminal board 30 may be fitted into the fitting groove 24 formed in the other of the terminal insertion groove 22 and the terminal board 30 while being slid.

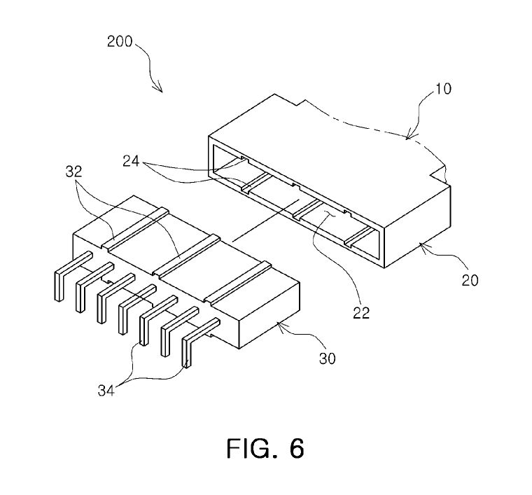

FIG. 6 is a partially exploded perspective view schematically showing a coil component according to another embodiment of the present invention. Only the terminal insertion part and the terminal board of FIG. 3 are partially shown in FIG. 6.

A coil component 200 according to the present embodiment is mainly different in configurations of a terminal insertion part 20 of a bobbin 10 and a terminal board 30 from the coil component 100 according to the above-mentioned embodiment of the present invention. Therefore, a detailed description of the same configuration as that of the above-mentioned embodiment will be omitted and a configuration different from that of the above-mentioned embodiment will be mainly described.

Referring to FIG. 6, in the coil component 200 according to the present embodiment, only an inlet surface of the terminal insertion groove 22 of the bobbin 10, through which the terminal board 30 is inserted, is opened. Further, the terminal board 30 according to the present embodiment may be insertedly coupled to the terminal insertion groove 22 through the above-mentioned inlet surface while being slid in an opposite direction to a direction in which the external connection terminals 34 protrude.

To this end, the fitting grooves 24 formed in the terminal insertion groove 22 may be disposed to be in parallel with the direction in which the external connection terminals 34 protrude.

The terminal board 30 may have a form similar to that of the terminal board 30 according to the above-mentioned embodiment except for a direction in which the fitting protrusions 32 are disposed.

In the case in which the terminal board 30 is inserted into the terminal insertion groove 22, the external connection terminals 34 of the terminal board 30 may be exposed to the outside through the inlet surface of the terminal insertion groove 22.

In the case in which the terminal insertion groove 22 is configured as described above, there is a defect that the terminal board 30 may be easily separated from the terminal insertion groove 22 in the direction in which the external connection terminals 34 protrude. However, this defect may be solved by configuring the terminal board 30 so as to be fitted into the terminal insertion groove 22, similar to the above-mentioned embodiment. In addition, since the terminal board 30 is not separated from the terminal insertion groove 22 by tension of the coils after the coils are connected to the external connection terminals 34, the above-mentioned defect may be solved.

On the other hand, in the terminal insertion groove 22 according to the present embodiment, only a single surface is opened. Therefore, the terminal insertion groove 22 according to the present embodiment may be manufactured more firmly than the terminal insertion groove 22 according to the above-mentioned embodiment and be resistant to external impact.

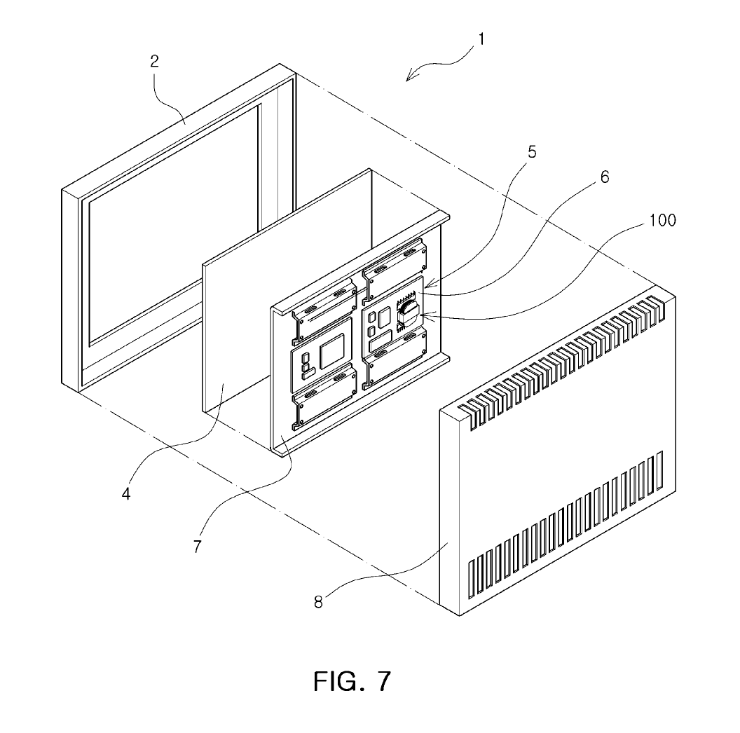

FIG. 7 is an exploded perspective view schematically showing a display device according to the embodiment of the present invention.

Referring to FIG. 7, a display device 1 according to the embodiment of the present invention may include a display panel 4, a switched mode power supply (SMPS) 5 having the coil component 100 mounted therein, and covers 2 and 8.

The covers 2 and 8 may include a front cover 2 and a back cover 8 and may be coupled to each other to thereby form a space therebetween.

The display panel 4 may be disposed in an internal space formed by the covers 2 and 8. As the display panel 4, various flat panel display panels such as a liquid crystal display (LCD), a plasma display panel (PDP), an organic light emitting diode (OLED), and the like, may be used.

The SMPS 5 may provide power to the display panel 4. The SMPS 5 may be formed by mounting a plurality of electronic components on a printed circuit board 6 thereof and particularly, may include at least one of the coil components 100 and 200 according to the above-mentioned embodiments, mounted therein.

The SMPS 5 may be fixed to a chassis 7 and be fixedly disposed in the internal space formed by the covers 2 and 8 together with the display panel 4.

The coil component according to the present invention as described above is not limited to the above-mentioned embodiments, but may be variously applied.

For example, the case in which the terminal board is fixedly coupled to the terminal insertion groove through the fitting has been described by way of example in the above-mentioned embodiments. However, the present invention is not necessarily limited thereto, but may be variously applied. That is, an adhesive member may be interposed between the terminal board and the terminal insertion groove to adhere the terminal board and the terminal insertion groove to each other.

In addition, the case in which the terminal board and the terminal insertion groove have a rectangular parallelepiped form has been described by way of example in the above-mentioned embodiments. However, the present invention is not necessarily limited thereto, but may be variously applied as needed. That is, the terminal board and the terminal insertion groove may have a cylindrical form or a polyprism form as needed.

In addition, the insulating type switching transformer among the coil components has been described byway of example in the above-mentioned embodiments. However, the present invention is not limited thereto, but may be variously applied to a component having a wound coil, such as a transformer for an inverter, a high frequency filter, or the like, or to an electronic device including the same.

As set forth above, the coil component according to the embodiments of the present invention includes the terminal board, separately from the bobbin. In addition, the terminal board is coupled to the bobbin to form the external connection terminals on the bobbin.

That is, since the terminal board and the bobbin are separately manufactured, the terminal board and the bobbin may be formed of different materials. Therefore, the bobbin is formed of a PET material so as to have a thin thickness, and the terminal board on which the external connection terminals are disposed is formed of a phenolic resin having relatively low thermal deformation, whereby the coil component having a small size and low thermal deformation may be manufactured.

Further, in the coil component according to the present embodiment, various terminal boards may be prepared and be selectively coupled to the bobbin as needed. That is, coils having various forms may be wound and used through a single coil component, and the terminal boards may be appropriately selected and used according to a shape or a kind of wound coil, an electrical condition that the coil component is applied, or the like. Therefore, the coil component according to the present embodiment may be easily used in various devices.

While the present invention has been shown and described in connection with the embodiments, it will be apparent to those skilled in the art that modifications and variations can be made without departing from the spirit and scope of the invention as defined by the appended claims.

What is claimed is:

1. A coil component comprising:
a bobbin including a winding part having a coil wound therein and a terminal insertion part having a terminal insertion groove formed therein; and
at least one terminal board including a plurality of external connection terminals and insertedly coupled to the terminal insertion part.

2. The coil component of claim 1, wherein the terminal board is insertedly coupled to the terminal insertion groove in a sliding scheme.

3. The coil component of claim 2, wherein the terminal board is insertedly coupled to the terminal insertion groove while being slid in a direction perpendicular to a direction in which the external connection terminals protrude.

4. The coil component of claim 2, wherein the terminal board is insertedly coupled to the terminal insertion groove while being slid in a direction opposite to a direction in which the external connection terminals protrude.

5. The coil component of claim 1, wherein the terminal board includes at least one fitting protrusion formed on one surface thereof, and the terminal insertion groove includes at least fitting groove into which the fitting protrusion is fitted.

6. The coil component of claim 5, wherein the fitting protrusion of the terminal board protrudes to be elongated in a direction parallel to a direction in which the external connection terminals are disposed.

7. The coil component of claim 1, wherein the terminal insertion groove is formed as a space having a rectangular form, and an inlet surface of the terminal insertion groove through which the terminal board is inserted and a surface of the terminal insertion groove in which the external connection terminals are disposed are opened to the outside.

8. The coil component of claim 7, wherein a surface of the terminal insertion groove opposing the inlet surface is closed, and the terminal board is supported by the surface of the terminal insertion groove opposing the inlet surface, such that insertion of the terminal board is limited.

9. The coil component of claim 1, wherein an inlet surface of the terminal insertion groove through which the terminal board is inserted is opened to the outside, and the external connection terminals of the terminal board are exposed to the outside through the inlet surface.

10. The coil component of claim 1, wherein the terminal board at least partially protrudes outwardly of the terminal insertion groove.

11. The coil component of claim 1, wherein the terminal board is formed of a material having thermal deformation lower than that of a material of the bobbin.

12. The coil component of claim 1, wherein the bobbin is formed of a resin material that is easily thermally deformed, and the terminal board is formed of a resin material having good deformation resistance even at high temperatures.

13. The coil component of claim 12, wherein the bobbin is formed of any one of polyphenylenesulfide (PPS), a liquid crystal polyester (LCP), polybutyleneterephthalate (PBT), and polyethyleneterephthalate (PET).

14. The coil component of claim 12, wherein the terminal board is formed of a phenolic resin.

15. A coil component comprising:
a bobbin including a winding part having a coil wound therein; and
at least one terminal board coupled to the bobbin in a sliding scheme.

16. The coil component of claim 15, wherein the terminal board includes a plurality of external connection terminals disposed in a row.

17. The coil component of claim 16, wherein the terminal board is provided in plural so that forms or arrangement intervals of the external connection terminals thereof are different from each other, is selectively coupled to the bobbin, and is exchangeable from the bobbin.

18. The coil component of claim 15, wherein the terminal board includes at least one fitting groove formed to be elongated in a direction in which it is slid, and the bobbin includes at least one fitting protrusion fitted into the fitting groove of the terminal board.

19. The coil component of claim 15, wherein the bobbin includes at least one fitting groove formed to be elongated in a direction in which the terminal board is slid, and the terminal board includes at least one fitting protrusion fitted into the fitting groove of the bobbin.

20. A display apparatus comprising:
a switched mode power supply having at least one coil component of claim 1 mounted on a substrate thereof;
a display panel receiving power supplied from the switched mode power supply; and
a cover protecting the display panel and the switched mode power supply.
